(19) United States
(12) Patent Application Publication
(10) Pub. No.: US 2005/0102830 A1
(43) Pub. Date: May 19, 2005

(54) Process for manufacturing a wiring substrate

(76) Inventors: Hajime Saiki, Niwa-gun (JP); Atsuhiko Sugimoto, Kagamigahara (JP)

Correspondence Address: STITES & HARBISON PLLC, 1199 NORTH FAIRFAX STREET, SUITE 900, ALEXANDRIA, VA, 22314, US

(21) Appl. No.: 10/989,411

(22) Filed: Nov. 17, 2004

(30) Foreign Application Priority Data
Nov. 18, 2003 (JP) P.2003-388498

(51) Int. Cl. H05K 3/00; C25D 5/02

(52) U.S. Cl. 29/847; 29/846; 205/125

(57) ABSTRACT

A process for manufacturing a wiring substrate, comprising: a step of forming thin copper film layers on surfaces of insulating resin layers by plating the same electrolessly with copper; a step of forming plated resists of a pattern over the thin copper film layers; a step of forming wiring pattern layers in clearances of the plated resists by plating the same electrolytically with copper; a step of removing the plated resists and the thin copper film layers just below the plated resists; a step of etching surfaces of the wiring pattern layers to remove a thickness of 1 μm or less from the wiring pattern layers; and a step of forming another insulating resin layers over the insulating resin layers and the wiring pattern layers etched.

### FIELD OF THE INVENTION

The present invention relates to a wiring substrate manufacturing process capable of forming a wiring pattern layer (or a built-up wiring layer) easily at a fine pitch.

### BACKGROUND ART

### BACKGROUND OF THE INVENTION

According to the trend of recent years for a high performance and a high signal-processing rate, there has been enhanced a demand for making the size of the wiring substrate smaller and the pitch of the wiring pattern layers finer.

For example, an insulating resin layer between one wiring pattern layer and an adjacent wiring pattern layer is generally restricted by a practical limit of the section of a length×a width of 25 μm×25 μm. However, it has been demanded that the length and the width are individually 20 μm or less.

In order to satisfy these demands, it is necessary not only to form the wiring pattern layer precisely in shape and size but also to make the etching allowance small and homogenous for roughening the surface.

Heretofore, however, there has been any disclosure on the technique, by which the etching allowance by the roughening treatment to roughen the surface of the wiring pattern layer formed by plating it with copper is suppressed to about 1 μm or less on an average, for example. Specifically, the roughening treatment thus far made is to roughen the surface of the wiring pattern layer into continuous asperities of a depth of about several μm so as to achieve an adhesion to the insulating resin layer (as referred to JP-A-2000-258430 (pages 1 to 12), for example).

As a result, this adhesion could be retained, but that roughening treatment was difficult for making the wiring pattern layer into a finer pitch.

### SUMMARY OF THE INVENTION

The invention contemplates to solve the aforementioned problems in the background art, and has an object to provide a wiring substrate manufacturing process for making the etching allowance small and homogenous for roughening the surface.

In order to achieve the aforementioned object, the invention has been conceived by specifying the using conditions of an etching liquid to be used for the roughening treatment and by etching crystal grains of the copper plating forming the wiring pattern layer shallowly and the vicinities of their intercrystalline boundaries deeply.

Specifically, according to the invention, there is provided a process for manufacturing a wiring substrate comprising: the step of forming thin copper film layers on the surfaces of insulating resin layers by plating the same electrolessly with copper; the step of forming plated resists of a predetermined pattern over the thin copper film layers; the step of forming wiring pattern layers in the clearances and so on of the plated resists by plating the same electrolytically with copper; the step of removing the plated resists and the thin copper film layers just below the former; the step of etching the surfaces of the wiring pattern layers to remove a thickness of 1 μm or less from the wiring pattern layers; and the step of forming new insulating resin layers over the insulating resin layers and the wiring pattern layers etched.

According to this process, the surfaces of the wiring pattern layers are removed to remove a thickness of 1 μm or less from the wiring pattern layers by the aforementioned etching so that the shaping precision and the sizing precision of the wiring pattern layers etched can rise and so that the clearance between the adjoining wiring pattern layers can be narrowed. As a result, the new insulating resin layers can be formed narrow in the clearance. Therefore, it is possible to manufacture such a wiring substrate easily and reliably as has the wiring pattern layers of a fine pitch. Here, the aforementioned plated resists are prepared by patterning an insulating film containing 30 to 50 wt. % (% by weight) of an inorganic filler into a predetermined pattern by the well-known photolithography technique.

According to the invention, there is also provided, as a preferable embodiment, a wiring substrate manufacturing process; wherein the step of etching the surfaces of the wiring pattern layers etches to remove a thickness of 1 μm or less from the wiring pattern layers excepting the vicinities of the intercrystalline boundaries of the electrolytic copper plating and remove a thickness of 1 μm or more from the wiring pattern layers at the vicinities of the intercrystalline boundaries of the electrolytic copper plating.

According to this process, the vicinities of the intercrystalline boundaries, in which impurities in the copper plating agglomerate, are etched deeper than 1 μm in a crack shape, but a thickness of 1 μm or less is removed at the surfaces of the crystal grains surrounded by the vicinities. Thus, it is possible to keep the shaping precision and the sizing precision of the wiring pattern layers reliably.

According to the invention, there is further provided, as a preferable embodiment, a wiring substrate manufacturing process, wherein a narrow one of the plated resists has a width of less than 20 μm, and wherein one narrow wiring line in the wiring pattern layers etched has a width of less than 20 μm. According to this process, it is possible to reliably provide a wiring substrate having wiring pattern layers of a fine pitch.

### BRIEF DESCRIPTION OF THE DRAWINGS

FIG. 1 is a schematic section showing one step of a process for manufacturing a wiring substrate according to the invention;

FIG. 2 is a schematic section showing a manufacturing process subsequent to FIG. 1;

FIG. 3 is a schematic section showing a manufacturing process subsequent to FIG. 2;

FIG. 4 is a schematic section showing a manufacturing process subsequent to FIG. 3;

FIG. 5 is a schematic section showing a manufacturing process subsequent to FIG. 4;

FIG. 6 is a schematic section showing a manufacturing process subsequent to FIG. 5;

FIG. 7 is a schematic section showing a manufacturing process subsequent to FIG. 6;

FIG. 8 is a schematic section showing a manufacturing process subsequent to FIG. 7;

FIG. 9 is a schematic section showing a manufacturing process subsequent to FIG. 8;

FIG. 10 is a schematic section showing a manufacturing process subsequent to FIG. 9;

FIG. 11 is a schematic section showing a manufacturing process subsequent to FIG. 10;

FIG. 12 is a schematic section showing a manufacturing process subsequent to FIG. 11;

FIG. 13 is an enlarged section of a portion of FIG. 12;

FIG. 14 is a schematic section showing an etching step subsequent to FIG. 13;

FIG. 15 is an enlarged section of a different portion of FIG. 12;

FIG. 16 is a schematic section showing an etching step subsequent to FIG. 15; and

FIG. 17 is a schematic section showing the manufacturing steps subsequent to FIGS. 14 and 16 and a wiring substrate obtained.

### DETAILED DESCRIPTION OF THE INVENTION

The best mode for carrying out the invention will be described in the following.

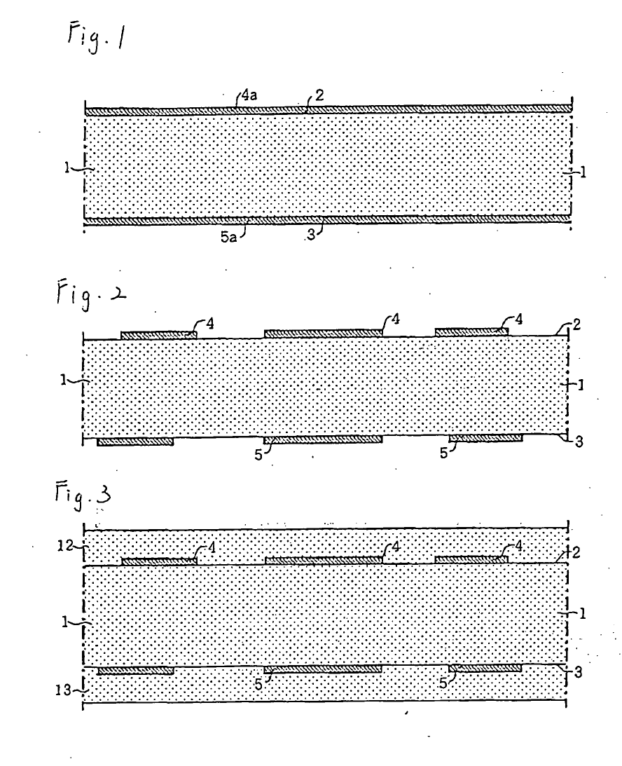

FIG. 1 is a section showing a core substrate 1 made of a bismaleimide triazine (BT) resin having a thickness of about 0.7 mm. This core substrate 1 is covered on its surface 2 and a back 3, respectively, with copper foils 4a and 5a having a thickness of about 70 μm. The not-shown photosensitive/insulating dry film is formed over those copper foils 4a and 5a and is subjected to an exposure and a development of a predetermined pattern. After this, the etching resist obtained is removed with a peeling liquid (according to the well-known subtractive method).

Here, a multi-panel having a plurality of core substrates 1 may be used so that the individual core substrates 1 may be subjected to a similar treatment step (as in the following individual steps).

As a result, the copper foils 4a and 5a become wiring layers 4 and 5 profiling the aforementioned pattern, as shown in FIG. 2.

Next, the surface 2 of the core substrate 1 and the wiring layer 4, and the back 3 of the core substrate 1 and the wiring layer 5 are individually covered thereover (or under the wiring layer 5) with an insulating film made of an epoxy resin containing an inorganic filler, as shown in FIG. 3, to form insulating resin layers 12 and 13. These insulating resin layers 12 and 13 have a thickness of about 40 μm, and contain 30 to 50 wt. % of an inorganic filler made of generally spherical SiO₂. Here, the inorganic filler has an average grain diameter of 1.0 μm or more and 10.0 μm or less.

Next, the surfaces of the insulating resin layers 12 and 13 are irradiated at their predetermined positions and along their thickness direction with the not-shown laser (e.g., a carbon monoxide gas laser in this embodiment). As a result, there are formed generally conical via holes 12a and 13a, which extend through the insulating resin layers 12 and 13 so that the wiring layers 4 and 5 are exposed to the bottom faces thereof, as shown in FIG. 4.

As shown in FIG. 4, moreover, the core substrate 1 and the insulating resin layers 12 and 13 are bored at their predetermined position with a drill to form a through hole 6 having an internal diameter of about 200 μm. Next, a plating catalyst containing Pd or the like is applied to the entire surfaces of the insulating resin layers 12 and 13 including the via holes 12a and 13a and is electrolessly or electrolytically plated thereover with copper.

As a result, copper-plated films 8a and 8b are formed all over the surfaces of the insulating resin layers 12 and 13, and a generally cylindrical through-hole conductor 7 having a thickness of about 40 μm is formed in the through hole 6, as shown in FIG. 5. At the same time, the via holes 12a and 13a are additionally plated therein with copper to form filled via conductors 14 and 15.

Next, the through-hole conductor 7 is filled on its inner side with a filler resin 9 containing an inorganic filler like before, as shown in FIG. 5. Here, the filler resin 9 may be either a conductive resin containing metal powder or an inconductive resin.

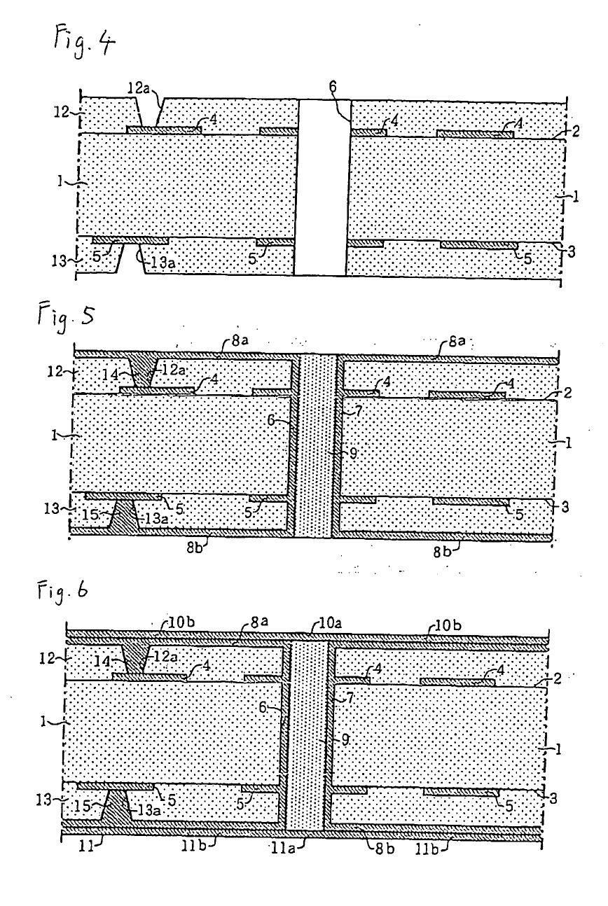

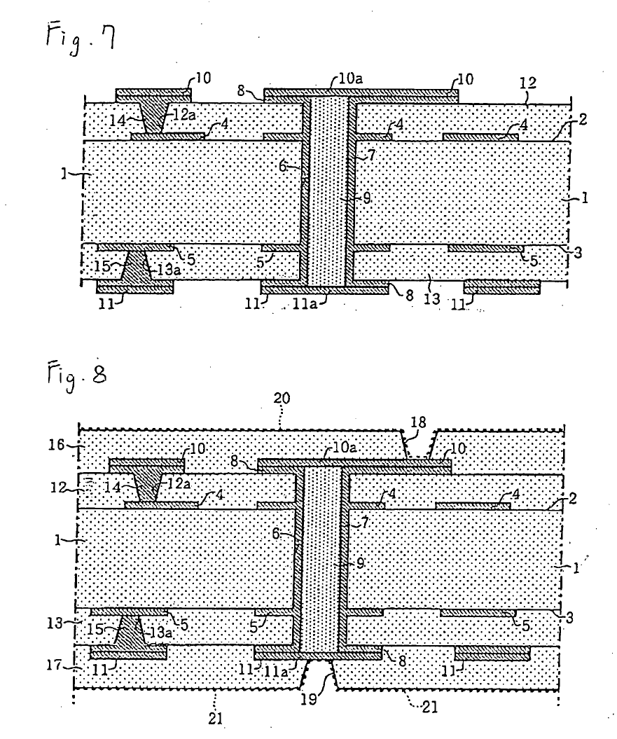

As shown in FIG. 6, moreover, the upper faces of the copper-plated films 8a and 8b and the two end faces of the filler resin 9 are electrically plated with copper to form copper-plated films 10b and 10b. Simultaneously with this, the filler resin 9 is cover-plated at 10a and 11a on its two end faces. Here, the copper-plated films 8a and 10b and the copper-plated films Bb and 11b individually have a thickness of about 15 μm.

Next, the not-shown photosensitive/insulating dry film is formed over the copper-plated films Ba and 10b and the copper-plated films 8b and 11b, and is subjected to an exposure and a development of a predetermined pattern. After this, the etching resist obtained and the copper-plated films 8a, 10b, 8b and 11b lying just below the former are removed with a well-known peeling liquid.

As a result, wiring layers 10 and 11 profiling the aforementioned pattern are formed on the surfaces of the insulating resin layers 12 and 13, as shown in FIG. 7.

Next, the insulating resin layer 12 and the wiring layer 10, and the insulating resin layer 13 and the wiring layer 11 are individually covered thereover (or under the layers 13 and 11) with an insulating film like before to form insulating resin layers 16 and 17.

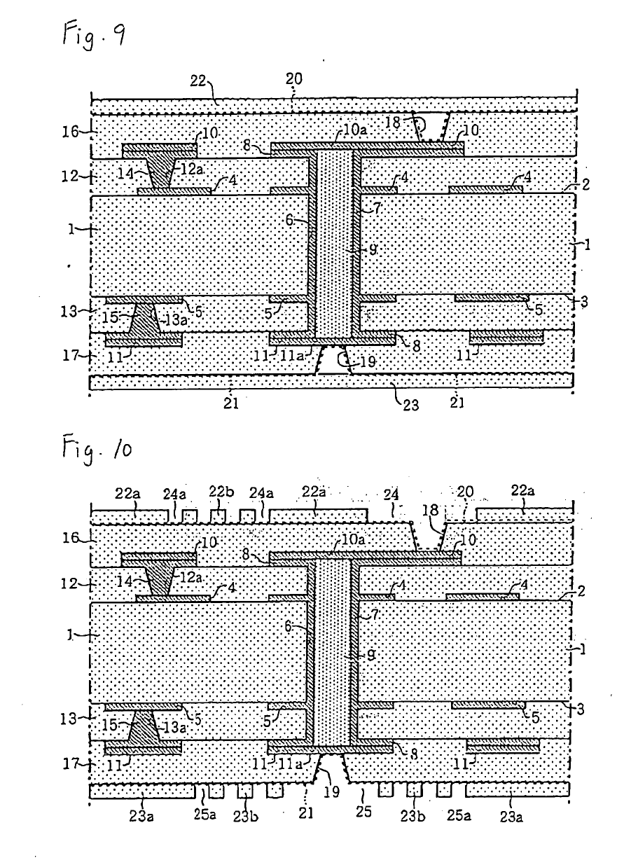

Moreover, the insulating resin layers 16 and 17 are irradiated on their surfaces at predetermined positions and along their thickness direction with the (not-shown) laser like before, to form generally conical via holes 18 and 19, which extend through the insulating resin layers 16 and 17 so that the wiring layers 10 and 11 are exposed to the bottom faces thereof, as shown in FIG. 8.

A plating catalyst like before is applied in advance to the entire surfaces of the insulating resin layers 16 and 17 including the inner faces of the aforementioned via holes 18 and 19, and is then electrolessly plated with copper, to form thin copper film layers 20 and 21 having a thickness of about 0.5 μm, as indicated by broken lines in FIG. 8.

Next, as shown in FIG. 9, the entire surfaces of the thin copper film layers 20 and 21 are covered with photosensitive/insulating films (or dry films) 22 and 23 made of an epoxy resin having a thickness of about 25 μm. These insulating films 22 and 23 are subjected to an exposure and a development of a predetermined pattern, and the exposed or unexposed portions are then removed with a peeling liquid.

As a result, plated resists 22a, 22b, 23a and 23b profiling the aforementioned pattern are formed on the surfaces of the thin copper film layers 20 and 21, as shown in FIG. 10. Of these, the narrow plated resists 22b and 23b having an elongated rectangular section have a width less than 20 μm (e.g., 18 μm in this embodiment), and clearances 24a and 25a between the aforementioned resists 22b and 23b and between these resists and the aforementioned resists 22a and 23a also have a width of less than 20 μm (e.g., 18 μm in this embodiment).

Simultaneously, wide clearances 24 and 25 are formed on the surfaces of the thin copper film layers 20 and 21 transversely adjoining the via holes 18 and 19.

Next, the thin copper film layers 20 and 21, which are positioned on the bottom faces of the clearances 24 and 25 and the clearances 24a and 25a and in the thin copper film layers 20 and 21, are electrolytically plated with copper.

As a result, filled via conductors 26 and 27 are individually formed in the via holes 18 and 19, and wiring pattern layers (or built-up wiring lines) 28 and 29 integral with the via conductors 26 and 27 are individually formed in the clearances 24 and 25, as shown in FIG. 11. Simultaneously with this, narrow wiring lines 28a and 29a having an elongated rectangular section of a width: less than 20 μm (e.g., 18 μmin this embodiment)×a length: about 25 μm are individually formed in the individual clearances 24a and 25a.

As exemplified in FIG. 12, moreover, the plated resists 22a and 22b (and 23a and 23b) and the thin copper film layer 20 (and 21) lying just below the former are removed with a peeling liquid.

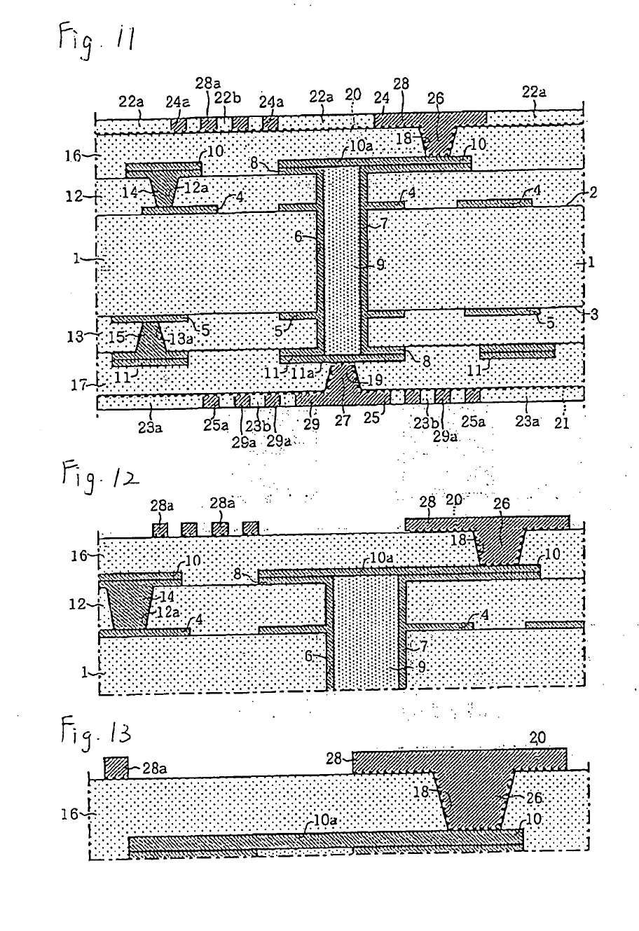

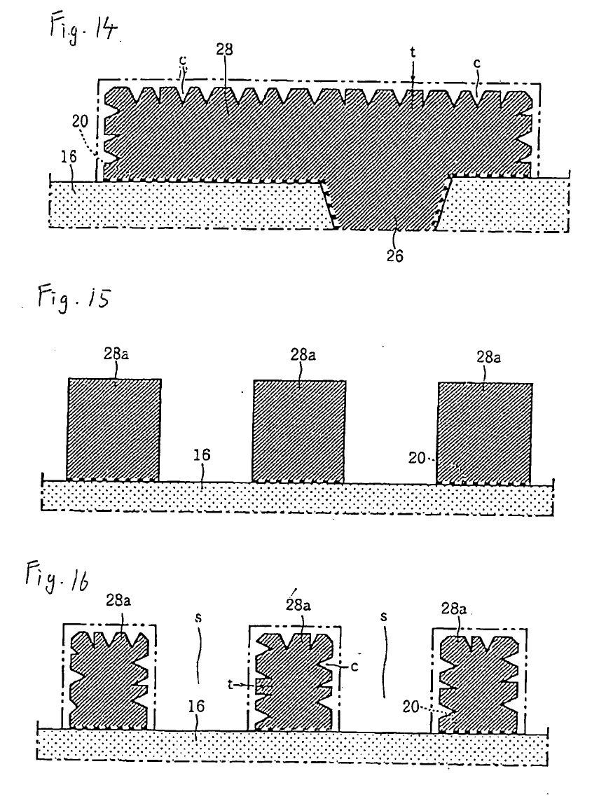

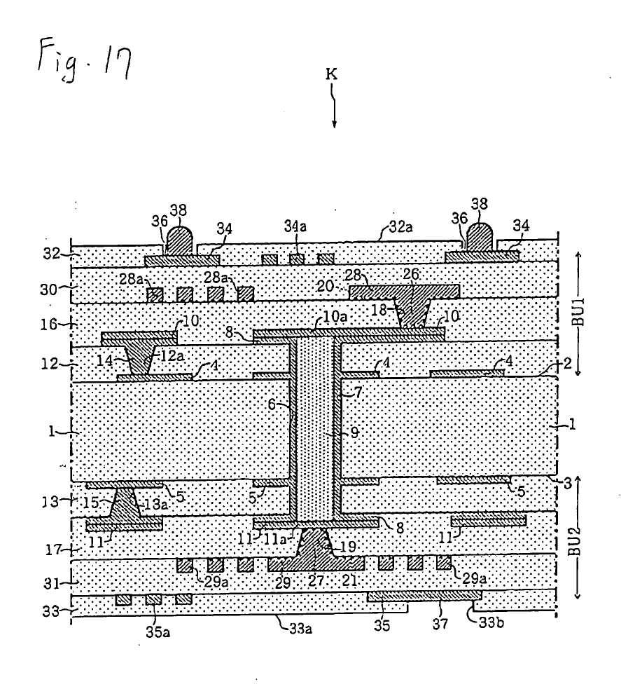

Next, as exemplified in FIG. 13 and FIG. 15, the surfaces of the wiring pattern layer 28 (29) and the plural narrow wiring lines 28a and 28a (29a and 29a) are etched rough. This etching treatment is carried out such that a corrosive liquid containing HCOOH and CuCl₂ is brought into contact with the surfaces of the aforementioned wiring layer 28 (29) and so on by a dipping method in an etching bath or a spray method, for example. The corrosive liquid preferably contains 15 wt. % or less of HCOOH and 5 wt. % or less of CuCl₂, and more preferably contains about 10 wt. % of HCOOH and 1 wt. % or less of CuCl₂ However, the amounts of HCOOH and CuCl₂ are not limited to the preferable ranges in the invention.

As a result, the wiring pattern layer 28 (29) has its entire surface in which a thickness t of about 1 μm or less is removed and its bottom face finely cracked at c in places with a depth of about 2 to 3 μm, as shown in FIG. 14. These cracks c are formed along the vicinities of the intercrystalline boundaries of the copper plating forming the wiring pattern layer 28 (29). Specifically, the aforementioned corrosive liquid etches most crystal grains of the electrolytically copper plating weakly, and the vicinities of the intercrystalline boundaries, in which relatively more impurities agglomerate, strongly.

At the same time, the plural narrow wiring lines 28a and 28a are also etched like above, so that a thickness t of about 1 μm or less is removed at their entire surfaces, and fine cracks c are formed at its bottom faces with a depth of about 2 to 3 μm, as shown in FIG. 16. Between the adjoining wiring lines 28a and 28a, as shown, there are formed clearances S which have sectional shapes and sizes like those of the wiring lines.

As has been described hereinbefore, the wiring pattern layers 28 (29) and the plural narrow wiring layers 28a and 28a (29a and 29a) contained in the are precisely formed by a semi-additive method, and their surfaces are substantially etched off so that an extremely small thickness of about 1 μm or less is removed, so that they can be formed at a fine pitch.

As shown in FIG. 17, moreover, the wide wiring pattern layer 29 and the plural narrow wiring line 29a like the aforementioned ones are also formed at the fine pitch on the surface of the insulating resin layer 17 on the side of the back 3 of the core substrate 1.

As shown in FIG. 17, moreover, an insulating resin layer (or a new insulating resin layer) 30 like before is formed on the surface of the insulating resin layer 16 having the aforementioned wiring pattern layers 28 and 28a formed thereover. An insulating resin layer (or a new insulating resin layer) 31 like before is formed on the surface of the insulating resin layer 17 having the aforementioned wiring pattern layers 29 and 29a formed thereover. The via holes (although not shown) are then formed like before at predetermined positions. After this, their surfaces are roughened.

Next, thin copper film layers like before are individually formed on the surfaces of the insulating resin layers 30 and 31 and in the aforementioned via holes, and insulating films like before are individually formed thereover, as shown in FIG. 17. These insulating films are subjected to an exposure and a development like before to form plated resists of a predetermined pattern, and the thin copper film layers positioned between those plated resists are electrolytically plated with copper like before.

As a result, wiring pattern layers 34, 34a, 35 and 35a are formed on the surfaces of the insulating resin layers 30 and 31 and are positioned at a fine pitch like before, as shown in FIG. 17. These wiring pattern layers contain the plural narrow wiring lines 34a and 35a.

Simultaneously with this, the filled via conductors (although not shown) are formed in the aforementioned via holes to connect the wiring pattern layers 28 and 34 and the wiring pattern layers 29 and 35. As a result, built-up layers BU1 and BU2 are formed over the surface 2 and the back 3 of the core substrate 1, as shown in FIG. 17. Here, the aforementioned plated resists and the thin copper film layers just below the former are peeled like before.

As shown in FIG. 17, moreover, a solder resist layer (or an insulating layer) 32 made of a resin like before and having a thickness of about 25 μm is formed over the surface of the insulating resin layer 30 having the wiring pattern layers 34 and 34a formed thereon. A solder resist layer (or an insulating layer) 33 like before is formed over the surface of the insulating resin layer 31 having the aforementioned wiring pattern layers 35 and 35a formed thereon.

The solder resist layers 32 and 33 are bored so deep at predetermined positions with a laser as to reach the wiring pattern layers 34 and 35, thereby to form a land 36 to be opened to a first principal face 32a and an opening 39 to be opened to a second principal face 33a, as shown in FIG. 17.

A solder bump 38 protruding higher than the first principal face 32a is formed on the land 36, so that electronic parts such as the not-shown IC chip can be mounted over the solder bump 38 through solder. Here, the solder bump 38 is made of an alloy of a low melting point such as Sn—Cu, Sn—Ag or Sn—Zn.

As shown in FIG. 17, moreover, the surface of a wiring line 37, which extends from the wiring pattern layer 35 and which is positioned on the bottom face of an opening 33b, is plated, although not shown, with Ni or Au to provide connection terminals to be connected with a printed substrate such as the not-shown mother board.

Through the individual steps thus far described, it is possible to provide a wiring substrate K, which comprises the built-up layer BU1 and the built-up layer BU1 over the surface 2 and the back 3 of the core substrate 1, as shown in FIG. 17. The built-up layer BU1 includes the wiring pattern layers 28, 28a, 34 and 34a wired at the fine pitch, and the built-up layer BU2 includes the wiring pattern layers 29, 29a, 35 and 35a.

Here, the wiring substrate K may also be formed to have the built-up layer BU1 exclusively over the surface 2 of the core substrate 1. In this mode, only the wiring layer 11 and the solder resist layer 33 are formed on the side of the back 3.

According to the process for manufacturing the wiring substrate K of the invention thus far described, the width of the narrow plated resist 22b formed by the semi-additive method is made less than 20 μm so that the narrow wiring lines 28 having a width less than 20 μm can be reliably formed in the clearances 24a between the adjoining the plated resists 22b and 22b, and so that the adjoining wiring lines 28a and 28a and so on can be wired at a fine pitch less than 20 μm. Moreover, the wiring pattern layers 28 and 28a and so on are etched over so that a thickness of 1 μm or less is removed at almost all surfaces, so that their sectional shapes and size precisions can be held. Moreover, the clearances S between the wiring pattern layers 28a and 28a can also be formed to have sections like before, so that the new insulating resin layer 30 can also be precisely formed.

The invention should not be limited to the mode of embodiment thus far described.

The individual steps of the aforementioned manufacturing process may also be performed with a large-sized multi-panel having a plurality of core substrates 1 or core units.

Moreover, the material for the core substrate should not be limited to the aforementioned BT resin but may be exemplified by an epoxy resin or a polyimide resin. Alternatively, it is also possible to use a composite material which is prepared by containing glass fibers in a fluorine resin having a three-dimensional net structure such as PTFE having continuous pores.

Alternatively, the material of the aforementioned core substrate may be ceramics. This ceramics may be alumina, silicic acid, glass ceramics or aluminum nitride, and may also be exemplified by a low-temperature sintered substrate which can be sintered at a relatively low temperature such as about 1,000° C. Moreover, a metal core substrate made of a copper alloy or a Ni alloy containing 42 wt. % of Fe may be used and is covered all over its surface with an insulating material.

Moreover, the mode may also be modified into a coreless substrate having no core substrate. In this modification, for example, the aforementioned insulating resin layers 12 and 13 act as the insulating substrate of the invention.

Moreover, the material for the aforementioned wiring layer 10 or the like may be not only the aforementioned Cu (copper) but also Ag, Ni or Ni—Au. Alternatively, the wiring layer 10 does not use the metal-plated layer but may also be formed by a method of applying a conductive resin.

Moreover, the aforementioned insulating resin layers 16 and 17 and so on may also be exemplified, if it contains the aforementioned inorganic filler, not only by the aforementioned resin composed mainly of an epoxy resin or but also by a polyimide resin, a BT resin or a PPE resin, which has similar heat resistance and pattern forming properties, or a resin-resin composite material which is prepared by impregnating a fluorine resin having a three-dimensional net structure such as PTFE having continuous pores with a resin such as an epoxy resin.)

Moreover, the via conductors need not be the aforementioned filled via conductor 26 but can be an inverted conical conformable via conductor which is not filled therein completely with a conductor. Alternatively, the via conductors may take a staggered shape, in which they are stacked while being axially shifted, or a shape, in which a wiring layer extending midway in the planar direction is interposed.

This application is based on Japanese Patent application JP 2003-388498, filed Nov. 18, 2003, the entire content of which is hereby incorporated by reference, the same as if set forth at length.

1. A process for manufacturing a wiring substrate, comprising:
a step of forming thin copper film layers on surfaces of insulating resin layers by plating the same electrolessly with copper;
a step of forming plated resists over the thin copper film layers;
a step of forming wiring pattern layers in clearances of the plated resists by plating the same electrolytically with copper;
a step of removing the plated resists and the thin copper film layers just below the plated resists;
a step of etching surfaces of the wiring pattern layers to remove a thickness of 1 μm or less from the wiring pattern layers; and
a step of forming another insulating resin layers over the insulating resin layers and the wiring pattern layers etched.

2. The process according to claim 1, wherein the step of etching is a step of etching surfaces of the wiring pattern layers to remove a thickness of 1 μm or less from the wiring pattern layers excepting vicinities of intercrystalline boundaries of electrolytic copper plating, and remove a thickness of 1 μm or more from the wiring pattern layers at the vicinities of intercrystalline boundaries.

3. The process according to claim 1, wherein one of the plated resists has a width of less than 20 μm, and one of wiring lines in the wiring pattern layers etched has a width of less than 20 μm.

4. The process according to claim 1, wherein the step of etching is carried out by the use of a corrosive liquid containing HCOOH and CuCl₂.

5. The process according to claim 1, wherein the step of etching is carried out by brining a corrosive liquid containing HCOOH and CuCl₂ into contact with the surfaces of the wiring pattern layers by a dipping method in an etching bath or a spray method.
